(19) United States
(12) Patent Application Publication
(10) Pub. No.: US 2017/0370021 A1
(43) Pub. Date: Dec. 28, 2017

(54) METHOD OF PREPARING FOR RE-OPERATION OF REACTOR FOR GROWING EPITAXIAL WAFER

(71) Applicant: LG SILTRON INC., Gumi-si, Gyeongsangbuk-do (KR)

(72) Inventors: Man-Kee CHO, Gumi-si (KR); Dong-Ho KANG, Gumi-si (KR)

(21) Appl. No.: 15/544,839

(22) PCT Filed: Dec. 23, 2015
(86) PCT No.: PCT/KR2015/014215

§ 371 Date: Jul. 19, 2017

(30) Foreign Application Priority Data
Jan. 22, 2015 (KR) 10-2015-0010781

(51) Int. Cl. C30B 25/14; C23C 16/44; C30B 25/08; C30B 25/12

(52) U.S. Cl. CPC C30B 25/14; C30B 25/12; C23C 16/4405; C30B 25/08

(57) ABSTRACT

Provided is a re-operation preparation process of a reaction chamber in which epitaxial growth is performed on a wafer. The re-operation preparation process of the reaction chamber includes disposing a susceptor provided in the reaction chamber and on which the wafer is seated at a preset first position and setting a flow rate of a hydrogen gas introduced through a main valve so that the flow rate is greater than that of a hydrogen gas introduced through a slit valve and moving the susceptor to a preset second position and setting an amount of hydrogen gas introduced through the main valve while the susceptor is maintained at the second position so that the amount of hydrogen gas is less than that of hydrogen gas introduced through the slit valve. Thus, moisture and contaminants stagnant in a lower portion of the reaction chamber may be smoothly discharged along a flow of the hydrogen gas toward a discharge hole.

### TECHNICAL FIELD

The present disclosure relates to a re-operation preparation process in a chamber, and more particularly, to a re-operation preparation method for forming an atmosphere under which moisture and impurities remaining in a chamber are removed after growth of an epitaxial wafer is finished to perform a subsequent epitaxial process.

### BACKGROUND ART

Conventional silicon wafers may be manufactured through a single crystal growth process, a slicing process, a grinding process, a wrapping process, a polishing process, and a cleaning process for removing an abrasive or foreign substances that are attached to the wafers after the wafers are polished. Such a wafer manufactured through the above-described processes may be called a polished wafer, and a wafer that is manufactured by growing another single crystal layer (an epitaxial layer) on the polished wafer may be called an epitaxial wafer.

The epitaxial wafer may have properties in which defects are fewer than those of the polished wafer, and a concentration and kind of impurities are controllable. Also, the epitaxial layer may be advantageous to improve yield of a semiconductor device and device characteristics due to high purity and superior crystal properties thereof. Chemical vapor deposition may be a process for growing a material on an object such as a semiconductor wafer to form a thin layer. Thus, the layer having conductivity may be deposited on the wafer so that the wafer has desired electrical characteristics.

A chemical vapor deposition device for depositing an epitaxial layer on a surface of a wafer includes a process chamber in which the deposition of the epitaxial layer is performed, a susceptor mounted therein, a heating lamp disposed on upper and lower portions of the process chamber, and a gas injection unit for injecting a source gas onto the wafer. The source gas injected through the gas injection unit may be injected onto the wafer placed on the susceptor to form an epitaxial layer.

When an epitaxial process that is performed at a high temperature is completed in a chamber of an epitaxial reactor for growing the epitaxial layer on the wafer, moisture containing metal impurities may exist in the chamber. When the impurities exist in the chamber, it may be difficult to manufacture an epitaxial wafer having high quality. Thus, when the process for manufacturing the epitaxial water is completed, the impurities remaining in the chamber have to be removed to form an atmosphere under which the epitaxial process is performed again.

When explaining a method for re-operating the epitaxial reactor according to the related art, a nitrogen gas is injected into the chamber having room temperature for three hours to ventilate the impurity particles within the chamber. Then, while the inside of the chamber is maintained to a high temperature for a predetermined time after the inner temperature of the chamber increases, a baking process using a hydrogen gas is performed to remove the remaining moisture or impurities.

However, in this method, the hydrogen gas may not flow in a vertical direction, but flow in a horizontal direction in the chamber. As a result, the remaining moisture or metal contaminants may exist in a lower portion of the chamber as ever. Here, it may be difficult to secure quality of the epitaxial wafer that is produced under the above-described conditions.

### DISCLOSURE

### Technical Problem

Embodiments provides a method in which a hydrogen gas flowing along a lower portion of a susceptor provided in a process chamber flows upward during a baking process to discharge contaminants stagnant in the lower portion to the outside of the process chamber, thereby reducing a re-operation time of a reactor in a re-operation preparation process of the reactor for manufacturing an epitaxial wafer.

### Technical Solution

In one embodiment, a re-operation preparation process of a reaction chamber in which epitaxial growth is performed on a wafer includes: disposing a susceptor provided in the reaction chamber and on which the wafer is seated at a preset first position and setting a flow rate of a hydrogen gas introduced through a main valve so that the flow rate is greater than that of a hydrogen gas introduced through a slit valve; and moving the susceptor to a preset second position and setting an amount of hydrogen gas introduced through the main valve while the susceptor is maintained at the second position so that the amount of hydrogen gas is less than that of hydrogen gas introduced through the slit valve.

The first position may be set to the same height as a preheating ring disposed on an outer circumference of the susceptor, and the second position may be set to be lower by a predetermined height than the first position.

### Advantageous Effect

In the method for preparing the reactor for the growth of the epitaxial wafer, the unstable atmosphere may be formed so that the gas flowing through the inside of the reaction chamber flows in the vertical direction to effectively discharge the moisture and contaminants, which are stagnant in the lower portion of the reaction chamber.

According to the embodiment, since the contaminants stagnant in the lower portion of the reaction chamber are quickly removed, the time taken to reach the minimum value of the MCLT for performing the re-operation of the reactor may be reduced. Therefore, the preparation time taken to perform the re-operation of the reactor may be reduced to improve the production yield of the epitaxial wafer.

### DESCRIPTION OF DRAWING

FIG. 1 is a view of an epitaxial growth apparatus, i.e., a cross-sectional view illustrating a first position of a susceptor when a baking process is performed in a process chamber.

FIG. 2 is a view of the susceptor in the epitaxial growth apparatus when viewed from an upper side.

FIG. 3 is a cross-sectional view illustrating a state in which the susceptor descends by a predetermined distance from a height of a preheating ring to move to a second position in a process for preparing a re-operation of the epitaxial growth apparatus according to an embodiment.

FIG. 4 is a graph illustrating a minority carrier life time (MCLT) level in the reaction chambers in the process for preparing the epitaxial reactor according to the related art and the embodiment.

FIG. 5 is a graph illustrating a MCLT level according to a variation in height of the susceptor in the process for preparing the epitaxial reactor according to an embodiment of Table 1.

### MODE FOR INVENTION

Although embodiments are described in detail with reference to the accompanying drawings, the present disclosure is not limited to the embodiments. Moreover, detailed descriptions related to well-known functions or configurations will be ruled out in order not to unnecessarily obscure subject matters of the present disclosure.

Embodiments provide a method in which process conditions and a position of the susceptor in an epitaxial reactor (reactor) are changed to allow contaminants stagnant in a lower portion of the epitaxial reactor to move upward, thereby forming an ascending current.

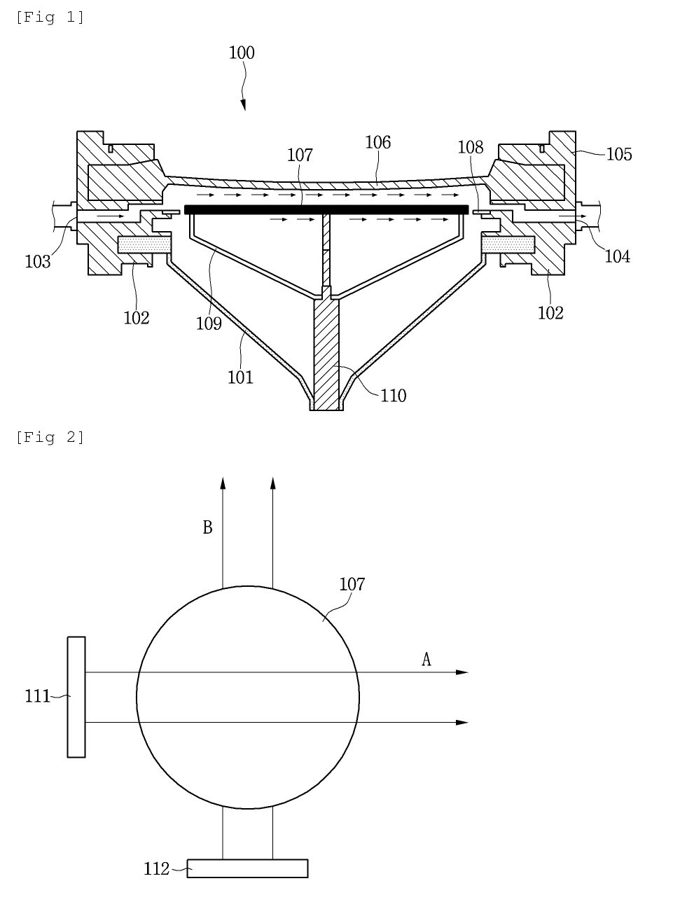

FIG. 1 is a view of an epitaxial growth apparatus, i.e., a cross-sectional view illustrating a first position of a susceptor when a baking process is performed in a process chamber.

Referring to FIG. 1, an epitaxial growth apparatus 100 may include upper and lower liners 105 and 102, an upper cover 106, a lower cover 101, a susceptor 107, a preheating ring 108, a susceptor support 109, a gas supply port 103, a gas discharge port 104, and a main shaft 110.

The gas supply port 103 connected to a gas supply line may be disposed on one side of the epitaxial growth apparatus 100, and the gas discharge port 104 connected to a gas discharge line may be disposed on the other side of the epitaxial growth apparatus 100. Also, the epitaxial growth apparatus 100 may include the lower cover 101 and the upper cover 106.

The lower liner 102 may be disposed to surround the susceptor 107, and the upper liner 105 may be disposed to face an upper portion of the lower liner 102. The preheating ring 108 may have a ring shape along an inner surface of the lower liner 102 that is adjacent to the susceptor 107 and be seated on the lower liner 102. Also, the preheating ring 108 may be disposed to surround the susceptor 107 so that a gas supplied onto a wafer has a uniform temperature.

The susceptor 107 may be a portion on which the wafer is mounted during epitaxial reaction. The susceptor 107 may be provided as a plate formed of a material such as carbon graphite and silicon carbide. The susceptor 107 may be supported by the main shaft 110 that is disposed on a lower portion thereof and the susceptor support 109 that is branched into several parts in an edge direction of the susceptor 107. As illustrated in FIG. 1, the epitaxial process may be performed in a state in which the susceptor 107 is fixed to the first position that has the same height as the preheating ring 108.

To manufacturing the epitaxial wafer, an epitaxial layer is vapor-grown under a high temperature in the reaction chamber. Thus, if metal impurities or remaining moisture exist in the reaction chamber when the epitaxial layer is grown, the manufactured epitaxial wafer may be contaminated by the metal impurities, and thus, it may be difficult to ensure quality of the epitaxial wafer.

Thus, a preventive maintenance (PM) may be performed in the reaction chamber after the various processes are performed. Here, after the PM is performed, the remaining moisture may be generated in the reaction chamber. A process for re-operating the epitaxial growth apparatus after the PM is performed may include a process of injecting a nitrogen gas into the chamber having room temperature for three hours to ventilate impurity particles in the reaction chamber, a process of rising the inside of the reaction chamber to a predetermined temperature, a process of performing the baking process using the hydrogen gas while maintaining the reaction chamber having the raised temperature to a high temperature for a predetermined time, a process of confirming whether a dopant exists in the reaction chamber, and a process of removing a metal contamination source remaining in the reaction chamber.

The above-described may be performed in the process of performing the baking process in the reaction chamber having the raised temperature. Thus, the moisture and contaminants remaining in the reaction chamber may be effectively discharged through the process for preparing the re-operation of the reaction chamber.

FIG. 2 is a view of the susceptor in the epitaxial growth apparatus when viewed from an upper side.

Referring to FIG. 2, a main valve 111 is disposed above the susceptor 107 at a side of the upper liner 105 having a gas inflow hole, and the hydrogen gas that is a carrier gas for moving a reaction gas and moving the impurities generated during the process is introduced through the main valve 111. The introduced hydrogen gas may flow on a top surface of the susceptor in a direction A that is a direction in which the gas is discharged.

Also, a slit valve 112 is disposed below the susceptor 107 in a direction that is perpendicular to the main valve 111, and the hydrogen gas that is the carrier gas for moving the reaction gas and moving the impurities generated during the process may be introduced through the slit valve 112. The hydrogen gas introduced through the slit valve 112 may flow to a lower side of the susceptor 107. However, the hydrogen gas may flow in a direction B, but substantially flow to be one-sided in the direction A by suction force of a gas discharge hole.

That is, the hydrogen gas introduced through the main valve may flow in the direction A between the top surface of the susceptor 107 and the upper cover 106. The hydrogen gas introduced through the slit valve may be introduced in the direction B that is perpendicular to the main valve to move from the lower side of the susceptor to the gas discharge hole.

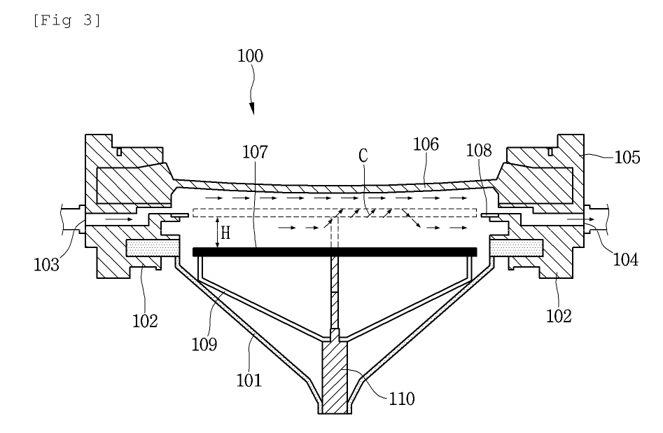

FIG. 3 is a cross-sectional view illustrating a state in which the susceptor descends by a predetermined distance from a height of the preheating ring to move to a second position in the process for preparing the re-operation of the epitaxial growth apparatus according to an embodiment.

Referring to FIG. 3, in the process for preparing the re-operation of the epitaxial growth apparatus 100, the baking process may be performed in the reaction chamber while the susceptor moves between the preset first position and the preset second position. The preset first position may be a position that is set to the same height as the preheating ring 108 disposed on an outer circumference of the susceptor, and the preset second position may be a position by which the susceptor descends by a predetermined height from the first position.

That is, according to an embodiment, while the baking process is performed in the reaction chamber in the process for preparing the re-operation of the epitaxial growth apparatus 100, the susceptor 107 may periodically ascend or descend to change a flow path of the hydrogen gas flowing along the upper and lower portion of the susceptor 107.

Particularly, in the process for preparing the re-operation of the epitaxial growth apparatus 100, the susceptor 107 may be maintained at the first position that has the same height as the preheating ring 108 for a predetermined time. A flow rate of the hydrogen gas introduced through the main valve in the state in which the susceptor is disposed at the first position at which the epitaxial process is performed may be set to be greater than that of the hydrogen gas introduced through the slit valve. Here, the hydrogen gas may be introduced at a flow rate of about 90 slm through the main valve and be introduced at a flow rate of about 20 slm through the slit valve.

Then, in the process of rising the inner temperature of the reaction chamber to a predetermined temperature, the susceptor 107 may move to the second position that descends by a predetermined height H in a direction of the lower cover 101 and then be maintained for a predetermined time. In an embodiment, while the susceptor moves to the second position, a flow rate of the hydrogen gas introduced through each of the main valve and the slit valve may be changed. In an embodiment, when the susceptor moves to the second position, the flow rate of the hydrogen gas introduced through the slit valve may be set to be greater than that of the hydrogen gas introduced through the main valve. As the susceptor moves to the second position, the hydrogen gas introduced through the slit valve may move to the upper side of the susceptor. Thus, the flow path of the hydrogen gas introduced through the slit valve may be changed.

That is, since the susceptor is disposed at the second position, the hydrogen gas introduced through the slit valve may flow along a flow C in which the hydrogen gas ascends to a flow line of the hydrogen gas introduced through the main valve. A dynamic status within the reaction chamber may be unstable due to the flow C, and thus, a flow of the moisture and contaminants remaining in the lower portion of the reaction chamber may be generated and then discharged to the outside of the reaction chamber along the flow of the hydrogen gas.

In an embodiment, the susceptor may periodically ascend or descend, and simultaneously, the flow rate of the hydrogen gas introduced through the main valve may be changed to be less than that of the hydrogen gas introduced through the slit valve. Preferably, when the susceptor descends, the hydrogen gas introduced through the main valve may be set to have a flow rate of about 5 slm to about 20 slm, and the hydrogen gas introduced through the slit valve may be set to have a maximum flow rate of about 30 slm.

Table 1 shows a recipe that is performed during the baking process in the process for preparing the re-operation of the epitaxial growth apparatus according to an embodiment.

TABLE 1

| step | 1 | 2 | 3 | 4 | 5 | 6 | 7 | 8 | 9 | 10 | 11 | 12 |
|---|---|---|---|---|---|---|---|---|---|---|---|---|
| | | Ramp | | Ramp | | Ramp | | Ramp | | Ramp | | Ramp |
| Max | 300 | 60 | 300 | 60 | 300 | 60 | 300 | 60 | 300 | 60 | 300 | 10 |
| time | | | | | | | | | | | | |
| Pos | 1st | 1st | 1st | 1st | 2nd | 1st | 1st | 1st | 2nd | 1st | 1st | 1st |
| Main | 90 | 90 | 90 | 90 | 20 | 90 | 90 | 90 | 20 | 90 | 90 | 90 |
| Slit | 20 | 20 | 20 | 20 | 30 | 20 | 20 | 20 | 30 | 20 | 20 | 20 |
| | | | | | Down | | | | down | | | |

As shown in Table 1, one cycle performed during the baking process may have a total of 12 processes. The above-described cycle may be performed three times. In each of the cycles, a period in which the inside of the reaction chamber is maintained to a predetermined temperature and a period in which the inside of the reaction chamber is changed to a predetermined temperature may be repeated.

First, in the first process, the reaction chamber may be raised in temperature to stabilize the inside of the reaction chamber for maximum 300 seconds (max time) at a predetermined temperature. Here, the susceptor may be disposed at a first position 1st at which the epitaxial process is performed, and the hydrogen gas may be introduced at a flow rate of about 90 slm through the main valve and at a flow rate of about 20 slm through the slit valve.

Then, in the second process, the inside of the reaction chamber may be set to have a temperature different from that in the first process. Thus, the inner temperature of the reaction chamber may increase or decrease. In the second process, the susceptor may be maintained at the first position for maximum 60 seconds, and the hydrogen gas may be continuously introduced at the flow rate of about 90 slm through the main valve and at the flow rate of about 20 slm through the slit valve.

In the fourth process, the first process and the second process may be repeatedly performed. In the fifth process, while the susceptor descends by a predetermined height to move a second position 2nd, the hydrogen gas may be changed in flow rate so that the hydrogen gas is introduced at a flow rate of about 20 slm through the main valve and at a flow rate of about 30 slm through the slit valve. Here, the fifth process may be performed for maximum 300 seconds.

In the sixth process, a process in which the inner temperature of the reaction chamber is changed for maximum 60 seconds and stabilized for maximum 300 seconds may be repeatedly performed up to the eleventh process. Here, the hydrogen gas may be introduced into the reaction chamber at a flow rate of about 90 slm through the main valve and at a flow rate of about 20 slm through the slit valve. Here, in the ninth process, the position of the susceptor may be changed again to the second position, and the flow rate of the hydrogen gas through the slit valve may be set to be greater than that of the hydrogen gas through the main valve.

As described above, the 12 processes may form one cycle. In an embodiment, since the cycle is repeated four times, the moisture and contaminants remaining in the reaction chamber may be reduced to reduce the re-operation time for the epitaxial growth apparatus.

That is, in an embodiment, since the flow rates of the hydrogen gas introduced through the main valve and the slit valve may be reversed when the susceptor is changed in position. Thus, the hydrogen gas flowing through the slit valve may move upward to allow the moisture and contaminants, which are not escaped to the outside, but entrapped in the lower portion of the reaction chamber, to move to the upper side of the susceptor, thereby inducing the discharge of the moisture and contaminants from the outside of the reaction chamber. This is done because the flow rate of the hydrogen gas flowing downward is reversed to be greater than that of the hydrogen gas flowing upward, and simultaneously, the susceptor moves downward to provide a flow path of the hydrogen gas flowing downward. That is, it is seen that the flow path of the hydrogen gas flowing along the lower side of the susceptor is changed to the upper side of the susceptor.

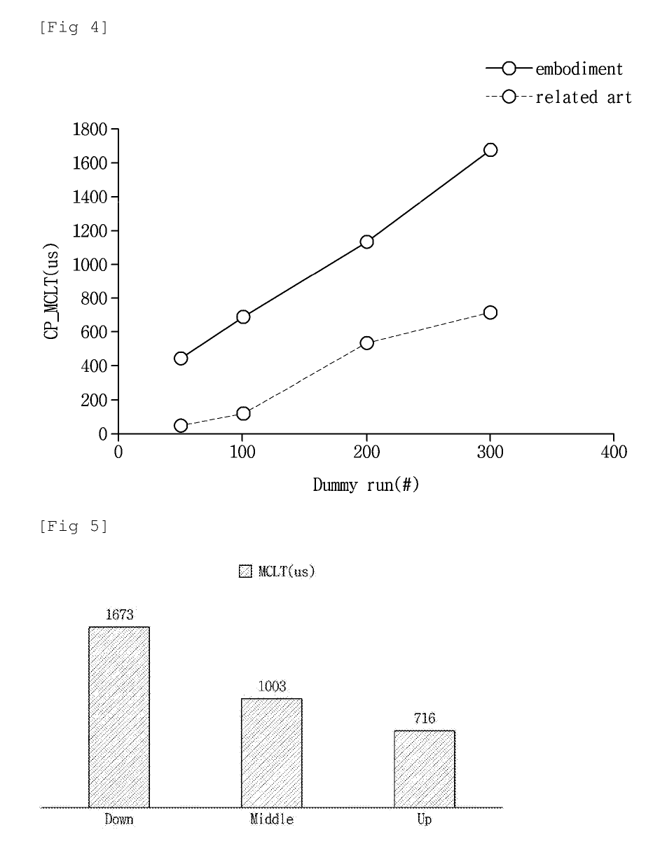

FIG. 4 is a graph illustrating a minority carrier life time (MOLT) level in the reaction chambers in the process for preparing the epitaxial reactor according to the related art and the embodiment. Particularly, when the baking process is performed in the process chamber while the susceptor is changed in position according to an embodiment, MCLT levels in the process chamber are compared.

The MCLT may become one measure for determining whether the re-operation of the epitaxial growth apparatus is completely prepared. The MCLT may denote a mean time taken to recombine excessive minority electrons. The more an amount of impurities in the reaction chamber increases, the more the MCLT decreases. In general, in the re-operation preparation process, various processes of the re-operation preparation process may be performed until the MCLT reaches a predetermined value.

In the graph of FIG. 4, a horizontal axis denotes the number of dummy run of the epitaxial wafer, and a vertical axis denotes a MCLT value. In the reaction chamber to which the above-described method is applied, the MCLT may significantly increase while the baking process is performed in the reaction chamber when compared to that according to the related art. In an embodiment, it is seen that the MCLT increases at least two times as the number of dummy run increases when compared to the method according to the related art. This represents that the re-operation time of the reaction chamber is significantly reduced.

FIG. 5 is a graph illustrating a MCLT level according to a variation in height of the susceptor in the process for preparing the epitaxial reactor according to an embodiment of Table 1.

Referring to FIG. 5, when the susceptor is in an up state, the susceptor is disposed at the first position at which the epitaxial process is performed. In the current embodiment, when the susceptor is in a down state, the susceptor descends by a height of about 9 mm and then is disposed at the second position. When the susceptor is in a middle state, the susceptor descends by a height of about 4.5 mm. As illustrated in FIG. 4, when the susceptor descends by a predetermined distance within the reaction chamber, it is seen that the MCLT level is significantly changed.

That is, when the susceptor descends by a height of about 4.5 mm, it is seen that a difference in level of the MCLT is not large when compared to the case in which the susceptor is disposed at the first position. When the susceptor descends by a height of about 9 mm, it is seen that a difference in level of the MCLT is large when compared to the case in which the susceptor is disposed at the first position. Thus, in the current embodiment, as the susceptor descends by the height of about 9 mm within the reaction chamber, the upward flow of the hydrogen gas may be well generated to effectively discharge the moisture and contaminants that are stagnant in the reaction chamber.

As described above, since the moisture and contaminants stagnant in the lower portion of the reaction chamber are effectively removed, the time taken to reach the minimum value of the MCLT for performing the re-operation of the reactor may be reduced. Therefore, the preparation time taken to perform the re-operation of the reactor may be reduced to improve the production yield of the epitaxial wafer.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

Since the embodiment is applied to the epitaxial growth apparatus for growing the epitaxial layer on the wafer, the industrial applicability is high.

1. A method for preparing a re-operation of an epitaxial growth apparatus as a re-operation preparation process of a reaction chamber in which epitaxial growth is performed on a wafer, the method comprising:
disposing a susceptor provided in the reaction chamber and on which the wafer is seated at a preset first position and setting a flow rate of a hydrogen gas introduced through a main valve so that the flow rate is greater than that of a hydrogen gas introduced through a slit valve; and
moving the susceptor to a preset second position and setting an amount of hydrogen gas introduced through the main valve while the susceptor is maintained at the second position so that the amount of hydrogen gas is less than that of hydrogen gas introduced through the slit valve.

2. The method according to claim 1, wherein the first position is set to the same height as a preheating ring disposed on an outer circumference of the susceptor.

3. The method according to claim 1, wherein the second position is set to be lower than the first position.

4. The method according to claim 1, wherein the susceptor periodically moves between the first position and the second position in a process in which baking is performed in the reaction chamber.

5. The method according to claim 4, wherein, when the susceptor moves between the first position and the second position, a flow rate of the hydrogen gas introduced through each of the main valve and the slit valve is changed.

6. The method according to claim 1, wherein, when the susceptor is disposed at the first position, the hydrogen gas introduced through the main valve has a flow rate of about 90 slm, and the hydrogen gas introduced through the slit valve has a flow rate of about 20 slm.

7. The method according to claim 1, wherein, when the susceptor is disposed at the second position, the hydrogen gas introduced through the main valve has a flow rate of about 5 slm to about 20 slm, and the hydrogen gas introduced through the slit valve has a flow rate of about 30 slm.

8. The method according to claim 1, wherein, in a process in which baking is performed in the reaction chamber, a period in which the inside of the reaction chamber is maintained at a uniform temperature and a period in which the inside of the reaction chamber is changed to a predetermined temperature are repeated.

9. The method according to claim 8, wherein, in the process in which the baking is performed in the reaction chamber, a process in which the inside of the reaction chamber is raised in temperature and maintained for maximum 300 seconds, and a process in which the inner temperature of the reaction chamber is changed for maximum 60 seconds are repeatedly performed.

10. A method for preparing a re-operation of an epitaxial growth apparatus as a re-operation preparation process of a reaction chamber in which epitaxial growth is performed on a wafer, the method comprising:
injecting a nitrogen gas into the chamber having room temperature for about three hours to ventilate impurity particles in the reaction chamber;
rising the inside of the reaction chamber to a predetermined temperature;
performing a baking process using the hydrogen gas while the reaction chamber having the raised temperature is maintained at a high temperature for a predetermined time;
confirming whether a dopant exists in the reaction chamber; and
removing a metal contaminant source remaining in the reaction chamber,
wherein, in the performing of the baking process in the reaction chamber, the susceptor periodically descends by a predetermined distance at a position at which an epitaxial process is performed, and when the susceptor descends, a flow rate of a gas introduced through a main valve is set so that the flow rate of the gas is less than that of a gas introduced through a slit valve.
